(19) United States
(12) Patent Application Publication
(10) Pub. No.: US 2013/0206460 A1
(43) Pub. Date: Aug. 15, 2013

(54) CIRCUIT BOARD FOR SEMICONDUCTOR DEVICE INSPECTION APPARATUS AND MANUFACTURING METHOD THEREOF

(71) Applicant: TOKYO ELECTRON LIMTED, (US)

(72) Inventors: Jun Mochizuki, Nirasaki City (JP); Hisatomi Hosaka, Nirasaki City (JP); Tomohisa Hoshino, Nirasaki City (JP)

(73) Assignee: TOKYO ELECTRON LIMTED, Tokyo (JP)

(21) Appl. No.: 13/763,781

(22) Filed: Feb. 11, 2013

(30) Foreign Application Priority Data
Feb. 14, 2012 (JP) 2012-029217

(51) Int. Cl. H05K 1/05; H05K 3/44

(52) U.S. Cl. CPC H05K 1/056; H05K 3/445
USPC 174/255; 29/846

(57) ABSTRACT

A circuit board for a semiconductor device inspection apparatus can have a small thermal expansion coefficient and high mechanical strength and can be easily manufactured with a reduced manufacturing cost. Furthermore, the circuit board includes a metal base body obtained by stacking and bonding a multiple number of metal plates, each having a through hole formed by an etching, such that the through holes of the metal plates are overlapped with each other to form a through hole; a resin layer formed on surfaces of the metal base body and on an inner wall surface of the through hole of the metal base body; and a conductor pattern formed to be electrically insulated from the metal base body by the resin layer.

### CROSS-REFERENCE TO RELATED APPLICATION

This application claims the benefit of Japanese Patent Application No. 2012-029217 filed on Feb. 14, 2012, the disclosures of which are incorporated herein by reference.

### FIELD OF THE INVENTION

The present disclosure relates to a circuit board for a semiconductor device inspection apparatus and a manufacturing method thereof.

### BACKGROUND OF THE INVENTION

In a semiconductor device manufacturing process, there has been used a semiconductor device inspection apparatus such as a prober configured to perform an electrical inspection on a semiconductor device formed on a semiconductor wafer or a handler configured to perform an electrical inspection on a packaged semiconductor device (see, for example, Patent Documents 1 and 2). In such a semiconductor device inspection apparatus, e.g., the prober, a tester and a circuit board for the semiconductor device inspection apparatus are used. The tester is configured to generate an inspection signal and to measure a signal from a target semiconductor device. The circuit board is configured to allow the tester to contact with probes brought into contact with electrode pads on the semiconductor wafer by changing a pitch of signal lines of the tester into a pitch of the probes.

In the circuit board for the semiconductor device inspection apparatus, since it is required to reduce expansion and contraction caused by temperature variation, the circuit board needs to be made of a material having a small thermal expansion coefficient. Further, since the circuit board is provided at a position to which a mechanical force is applied, the circuit board also needs to have sufficient mechanical strength. For these reasons, it is difficult to use a resin substrate for the circuit board. Accordingly, a ceramic substrate has been conventionally used.

Patent Document 1: Japanese Patent Laid-open Publication No. 2010-002302

Patent Document 2: Japanese Re-publication of International PCT Application No. WO 2009/104589

As mentioned above, since the circuit board for the semiconductor device inspection apparatus needs to have a small thermal expansion coefficient and high mechanical strength, a ceramic has been used as a material for forming the circuit board. Since, however, the ceramic is expensive and difficult to be processed, a manufacturing cost of the circuit board for the semiconductor device inspection apparatus has been increased.

### BRIEF SUMMARY OF THE INVENTION

In view of the foregoing problems, illustrative embodiments provide a circuit board for a semiconductor device inspection apparatus, which has a small thermal expansion coefficient and high mechanical strength and can be easily manufactured with a reduced manufacturing cost. Further, illustrative embodiments provide a manufacturing method for the circuit board for the semiconductor device inspection apparatus.

In accordance with one aspect of an illustrative embodiment, there is provided a circuit board for a semiconductor device inspection apparatus. The circuit board includes a metal base body obtained by stacking and bonding a multiple number of metal plates, each having a through hole formed by an etching, such that the through holes of the metal plates are overlapped with each other to form a through hole; a resin layer formed on surfaces of the metal base body and on an inner wall surface of the through hole of the metal base body; and a first conductor pattern formed to be electrically insulated from the metal base body by the resin layer.

In accordance with another aspect of the illustrative embodiment, there is provided a method for manufacturing a circuit board for a semiconductor device inspection apparatus. The method includes forming a through hole at a portion of each of metal plates by an etching; obtaining a metal base body by stacking and bonding the metal plates through a diffusion bonding such that the through holes are overlapped with each other to form a through hole; forming a resin layer on surfaces of the metal base body and on an inner wall surface of the through hole of the metal base body; and forming a conductor pattern electrically insulated from the metal base body by the resin layer.

In accordance with the illustrative embodiments, it is possible to provide the circuit board for a semiconductor device inspection apparatus, which has a small thermal expansion coefficient and high mechanical strength and can be easily manufactured with a reduced manufacturing cost. Further, it is also possible to provide a manufacturing method for the circuit board for the semiconductor device inspection apparatus.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a schematic configuration view illustrating a probe apparatus in accordance with illustrative embodiments;

FIG. 2 is a diagram illustrating a part of a manufacturing process in accordance with a first illustrative embodiment;

FIG. 3 is a diagram illustrating a part of the manufacturing process in accordance with the first illustrative embodiment;

FIG. 4 is a diagram illustrating a part of the manufacturing process in accordance with the first illustrative embodiment;

FIG. 5 is a diagram illustrating a part of the manufacturing process in accordance with the first illustrative embodiment;

FIG. 6 is a diagram illustrating a part of a manufacturing process in accordance with a second illustrative embodiment;

FIG. 7 is a diagram illustrating a part of the manufacturing process in accordance with the second illustrative embodiment;

FIG. 8 is a diagram illustrating a part of the manufacturing process in accordance with the second illustrative embodiment; and

FIG. 9 is a diagram illustrating a part of the manufacturing process in accordance with the second illustrative embodiment.

### DETAILED DESCRIPTION OF THE INVENTION

Hereinafter, illustrative embodiments will be described in detail with reference to the accompanying drawings.

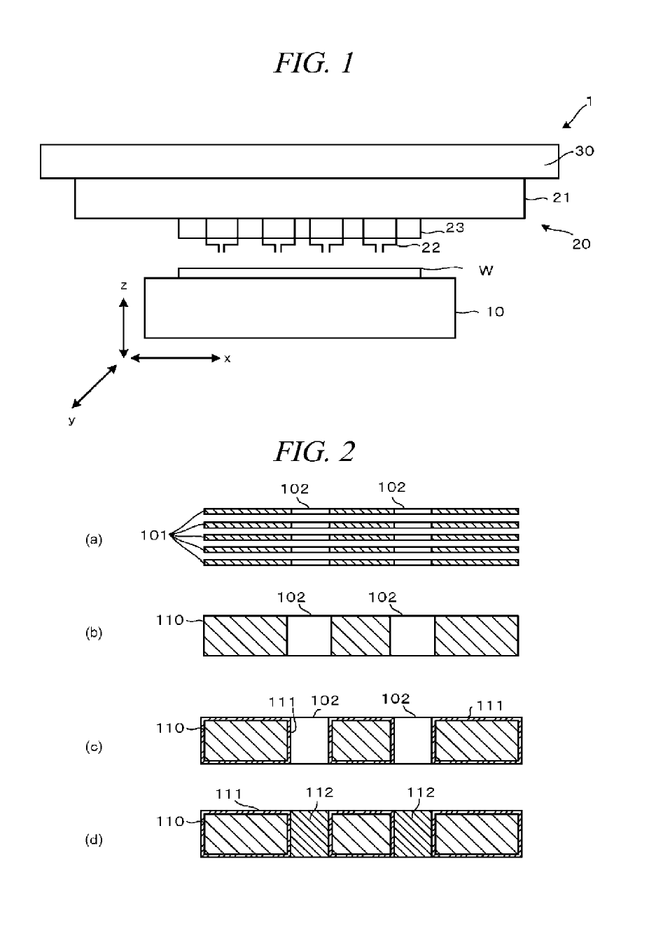

A configuration of a probe apparatus as a semiconductor device inspection apparatus will be first explained with reference to FIG. 1. The probe apparatus is configured to inspect a semiconductor device formed on a semiconductor wafer W. As illustrated in FIG. 1, the probe apparatus 1 includes a mounting table 10 for mounting thereon the semiconductor wafer W. The mounting table 10 includes a non-illustrated driving device and is configured to be movable in x, y, and z directions, as indicated by arrows in FIG. 1.

A probe card 20 is provided above the mounting table 10. The probe card 20 includes a circuit board 21 for the semiconductor device inspection apparatus (hereinafter, simply referred to as a “circuit board 21”); a multiple number of probes 22 electrically connected with the circuit board 21; and a probe supporting plate 23 for supporting the probes 22. Further, a test head 30 is provided above the probe card 20, and the test head 30 is connected to a tester that inspects the semiconductor device by sending an inspection signal to the semiconductor device and detecting a signal from the semiconductor device.

Each probe 22 is made of a metallic conductive material in a needle shape. The probes 22 are arranged to correspond to electrodes of the semiconductor device formed on the semiconductor wafer W. The probes 22 penetrate the probe supporting plate 23 in a thickness direction thereof and are also supported by the probe supporting plate 23. Leading ends of the probes 22 are protruded from a bottom surface of the probe supporting plate 23, and base ends of the probes 22 are connected to first electrode terminals (not shown) of the circuit board 21.

As stated above, the first electrode terminals having the same pitch as a pitch (e.g., a micron order) of the probes 22 are provided on a bottom surface of the circuit board 21 in FIG. 1. Meanwhile, second electrode terminals having the same pitch as a pitch (e.g., a millimeter order) of electrodes of the test head 30 of the tester are provided on a top surface of the circuit board 21 in FIG. 1. In this way, the circuit board 21 changes an electrode pitch by multi-layered electrode patterns.

When performing an electrical inspection of the semiconductor device formed on the semiconductor wafer W by using the probe apparatus 1 having the above-described configuration, the semiconductor wafer W is mounted on the mounting table 10 and lifted up by the mounting table 10. By bringing each electrode of the semiconductor device into contact with corresponding one of the probes 22, the electrodes and the probes 22 are electrically connected, and quality of an electrical characteristic of the semiconductor device is inspected by the tester connected to the test head 30.

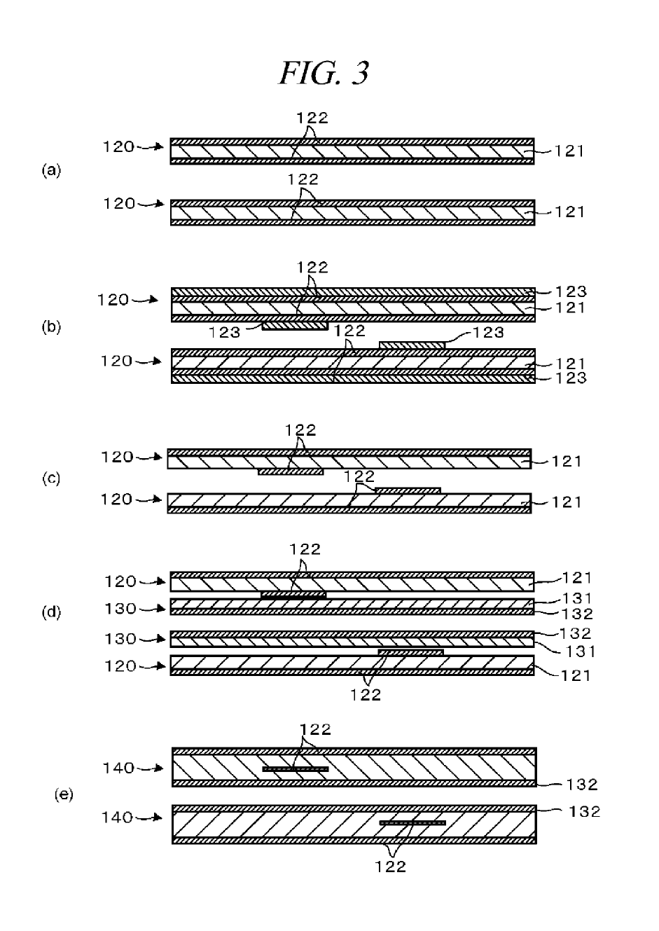

Now, a manufacturing process of the circuit board for the semiconductor device inspection apparatus in accordance with a first illustrative embodiment will be elaborated with reference to FIGS. 2 to 5.

As depicted in FIG. 2(a), in accordance with the first illustrative embodiment, a through hole 102 is formed at a certain portion of each of multiple metal plates 101 by a wet etching or a dry etching with a mask formed by, e.g., a photolithography process.

By way of example, each metal plate 101 may be formed by a plate member made of a metal having a small expansion coefficient, e.g., having a small linear expansion coefficient (α(×10⁻⁶/°C.)) equal to or smaller than about 10.0, more desirably, equal to or smaller than about 6.0. To elaborate, an iron-nickel alloy such as a 42 alloy or an iron-nickel-cobalt alloy such as Kovar may be used.

Further, desirably, the metal plate 101 may have a thickness ranging from about 0.01 mm to about 0.5 mm. If a plate having a thickness larger than about 0.5 mm is used, an inner diameter of the through hole 102 formed by the etching may be small at a middle portion of the plate in a thickness direction thereof while being large at both ends of the plate in the thickness direction thereof. By using a plate having a thickness ranging from about 0.01 mm to about 0.5 mm, the inner diameter of the through hole 102 formed by the etching can be substantially uniformized.

Then, as shown in FIG. 2(b), a certain number of the metal plates 101 having the through holes 102 formed by the etching are stacked such that the through holes 102 thereof are overlapped with each other to form a through hole 102. Then, the metal plates 101 are bonded to each other by a diffusion bonding so that a metal base body 110 is obtained. The entire thickness of the metal base body 110 may depend on a thickness required for the circuit board for the semiconductor device inspection apparatus. For example, the thickness of the metal base body 110 may range from about 1 mm to about 20 mm. Accordingly, the number of the stacked metal plates 101 may range from about 2 sheets to about 2000 sheets.

Thereafter, as illustrated in FIG. 2(c), a coating layer 111 made of an insulating resin is formed on surfaces of the metal base body 110 and on an inner wall surface of the through hole 102. The coating layer 111 is formed to electrically insulate the metal base body 110 from a conductive layer to be described later and to prevent a plating film from being formed on outer surfaces of the metal base body 110.

Subsequently, as illustrated in FIG. 2(d), an insulating resin 112 is filled into the through hole 102, so that a base member (core member) of the circuit board for the semiconductor device inspection apparatus is obtained.

Meanwhile, as depicted in FIG. 3(a), in addition to the metal base body 110, a multiple number of laminated members 120 are prepared. Each laminated member 120 is obtained by forming a conductive layer 122 made of, e.g., a copper foil on both surfaces of an insulating layer 121 made of, e.g., a resin.

Then, as depicted in FIG. 3(b), a resist mask 123 having a preset pattern is formed on each laminated member 120 by, e.g., the photolithography process.

Then, as depicted in FIG. 3(c), the conductive layer 122 of the laminated member 120 is etched by using the resist mask 123 as a mask, so that the conductive layer 122 is patterned to have a certain pattern. Then, the resist mask 123 is removed.

Thereafter, as depicted in FIG. 3(d), a member having an insulating layer 131 made of, e.g., a resin and a conductive layer 132 made of, e.g., a copper foil, i.e., a resin-attached copper foil 130 of this illustrative embodiment is stacked on each laminated member 120.

Thereafter, as shown in FIG. 3(e), the resin-attached copper foil 130 and the laminated member 120 are pressed together, so that a laminated plate 140 is obtained.

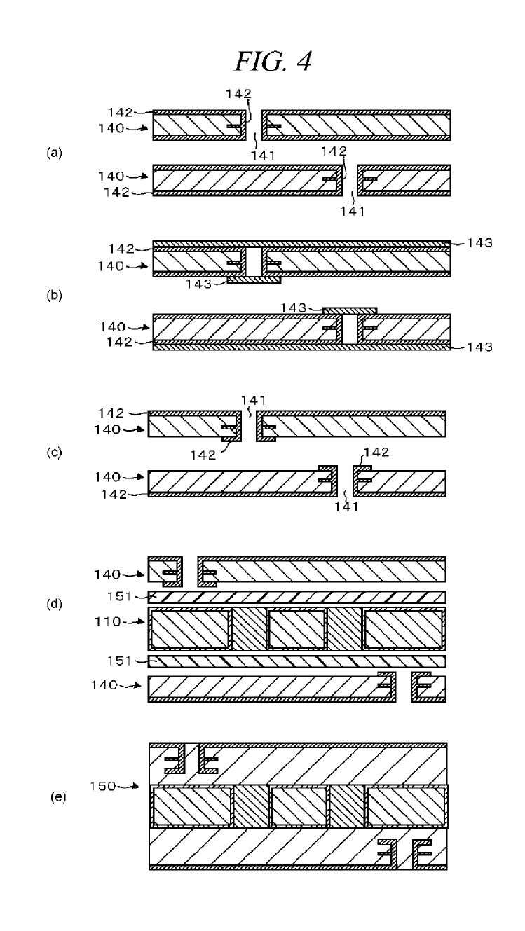

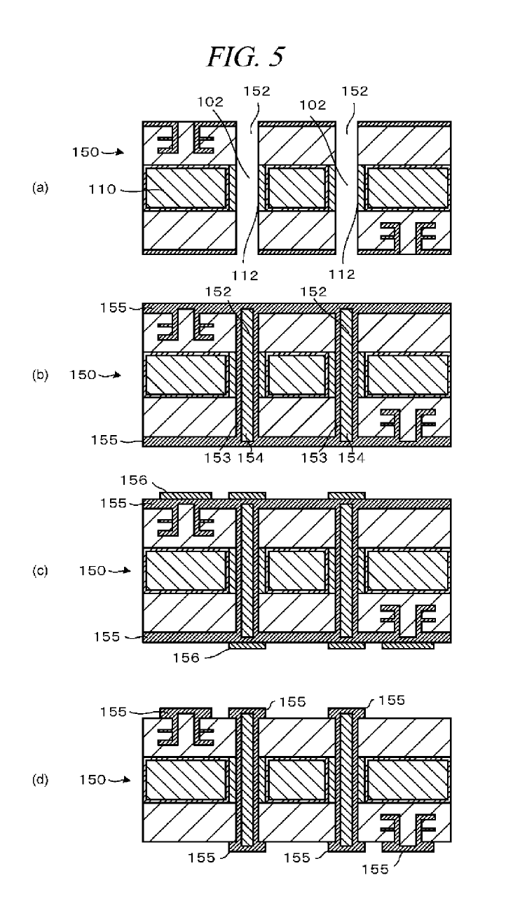

Then, as illustrated in FIG. 4(a), a through hole 141 serving as a SVH (Surface Via Hole) is formed in a certain portion of each laminated plate 140. Then, a conductive layer 142 is formed on an inner wall surface of the through hole 141 and on a front surface and a rear surface of the laminated plate 140 by, e.g., the plating.

Subsequently, as depicted in FIG. 4(b), a resist mask 143 having a certain pattern is formed on each laminated plate 140 by, e.g., the photolithography process.

Then, as illustrated in FIG. 4(c), the conductive layer 142 of each laminated plate 140 is etched by using the resist mask 143 as a mask, so that the conductive layer 142 is patterned to have a certain pattern. Then, the resist mask 143 is removed.

Thereafter, as shown in FIG. 4(d), the laminated plates 140 are attached to both surfaces of the metal base body 110 by using an adhesive resin 151. As a result, a laminated body 150 is obtained, as illustrated in FIG. 4(e).

Then, as shown in FIG. 5(a), a through hole 152 is formed on a portion of the laminated body 150, where the through hole 102 of the metal base body 110 is formed. When forming the through hole 152, since the through hole 152 is not formed in a metal portion of the metal base body 110 but formed in the resin 112 filled into the through hole 102, it is possible to easily form the through hole 152.

Subsequently, as depicted in FIG. 5(b), a conductive layer 153 is formed on an inner wall surface of the through hole 152 of the laminated body 150 and on a front surface and a rear surface of the laminated body 150 by, e.g., the plating. Then, after filling a resin 154 into the through hole 152, a conductive layer 155 is formed on the front surface and the rear surface of the laminated body 150 by the plating.

Then, as shown in FIG. 5(c), a resist mask 156 having a certain pattern is formed on the conductive layer 155 by, e.g., the photolithography process.

Thereafter, as illustrated in FIG. 5(d), the conductive layer 155 is etched by using the resist mask 156 as a mask, and the resist mask 156 is then removed.

In the circuit board for the semiconductor device inspection apparatus manufactured through the above-described process, the metal base body 110 formed by stacking and bonding the multiple metal plates 101 made of, e.g., the 42 alloy having a low expansion coefficient is used as the core member, and the conductor pattern is formed on the inner wall surface of the through hole 102 and on the front surface and the rear surface of the metal base body 110 via the insulating layer. Accordingly, it is possible to obtain the circuit board for the semiconductor device inspection apparatus having a low expansion coefficient and high mechanical strength. Further, since the through hole 102 is formed in the metal plate 101 by the etching previously before the metal plates 101 are stacked and bonded, it is not required to drill a metal portion to form the through hole. Thus, the circuit board can be manufactured easily, so that a manufacturing cost thereof can be reduced.

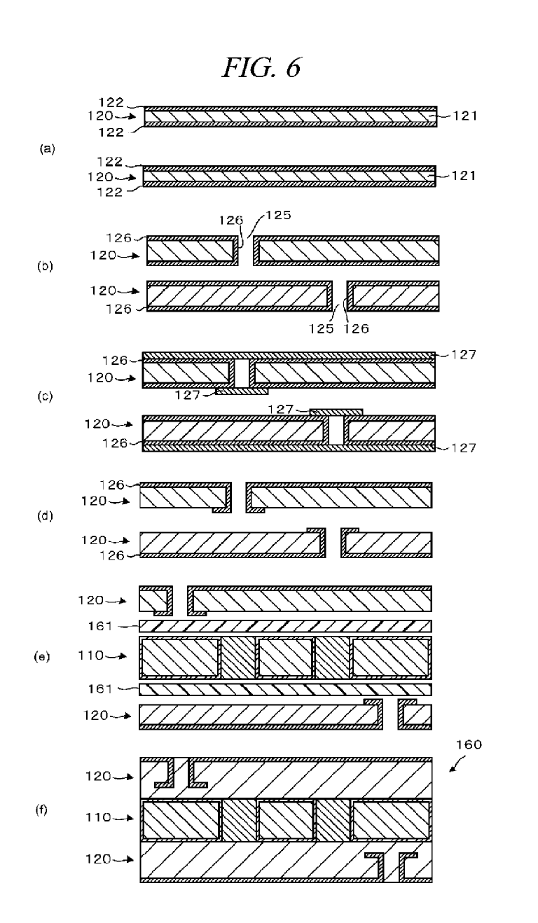

Now, a manufacturing method of the circuit board for the semiconductor device inspection apparatus in accordance with a second illustrative embodiment will be explained. Since a process for forming the metal base body 110 by bonding the metal plates 101 is the same as that described in FIG. 2, redundant description will be omitted. In this manufacturing process, as shown in FIG. 6(a), a multiple number of the laminated members 120 are prepared. Each laminated member 120 is obtained by forming the conductive layer 122 made of, e.g., a copper foil on both surfaces of the insulating layer 121 made of, e.g., a resin.

Then, as shown in 6(b), a through hole 125 serving as a SVH (Surface Via Hole) is formed in a certain portion of each laminated member 120. Then, a conductive layer 126 is formed on an inner wall surface of the through hole 125 and on a front surface and a rear surface of the conductive layer 122 by, e.g., the plating.

Subsequently, as shown in FIG. 6(c), a resist mask 127 having a certain pattern is formed on the conductive layer 126 by, e.g., the photolithography process.

Thereafter, as depicted in FIG. 6(d), the conductive layer 126 of each laminated member 120 is etched by using the resist mask 127 as a mask, and the conductive layer 126 is patterned to have a certain pattern. Then, the resist mask 127 is removed.

Then, without stacking a resin-attached copper foil or the like, the laminated members 120 are attached to both surfaces of the metal base body 110 by using an adhesive resin 161, as shown in FIG. 6(e). As a result, a laminated body 160 is obtained as shown in FIG. 6(f).

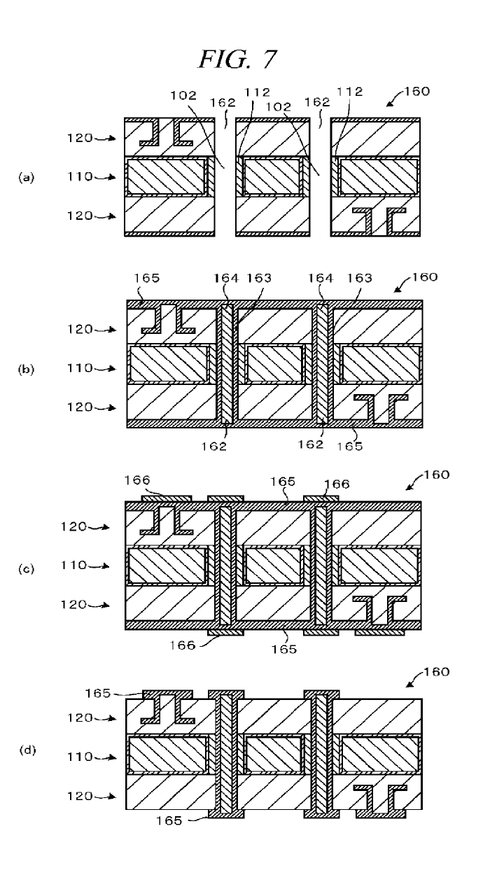

Then, as illustrated in FIG. 7(a), a through hole 162 is formed on a portion of the laminated body 160, where the through hole 102 of the metal base body 110 is formed. When forming the through hole 162, since the through hole 162 is not formed in the metal portion of the metal base body 110 but formed in the resin 112 filled into the through hole 102, it is possible to easily form the through hole 162.

Subsequently, as depicted in FIG. 7(b), a conductive layer 163 is formed on an inner wall surface of the through hole 162 of the laminated body 160 and on a front surface and a rear surface of the laminated body 160 by, e.g., the plating. Then, after filling a resin 164 into the through hole 162, a conductive layer 165 is formed on the front surface and the rear surface of the laminated body 160 by the plating.

Then, as shown in FIG. 7(c), a resist mask 166 having a certain pattern is formed on the conductive layer 165 by, e.g., the photolithography process.

Thereafter, as illustrated in FIG. 7(d), the conductive layer 165 is etched by using the resist mask 166 as a mask, and the resist mask 166 is then removed.

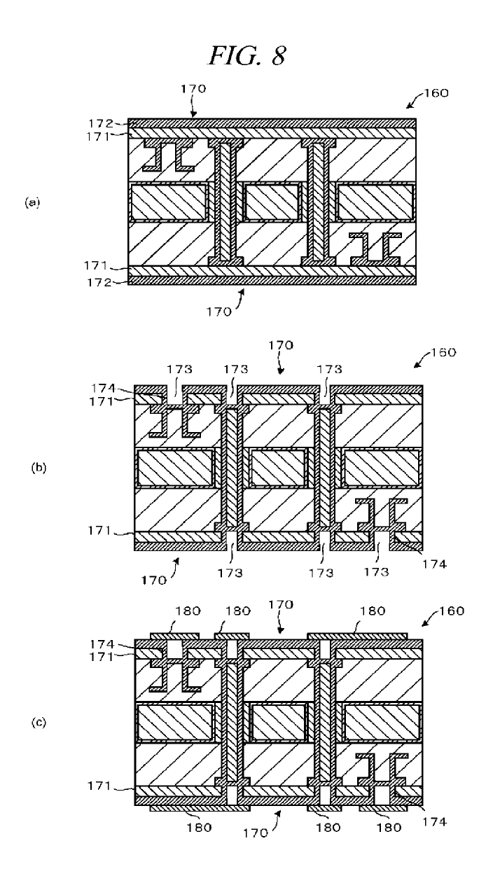

Thereafter, as shown in FIG. 8(a), a build-up layer 170 having an insulating layer 171 and a conductive layer 172 is formed on both surfaces of the laminated body 160.

Then, as illustrated in FIG. 8(b), a via hole 173 is formed in a certain portion of the build-up layer 170 of the laminated body 160 by using laser, and a conductive layer 174 is formed on an inner wall surface of the via hole 173 and on the conductive layer 172.

Subsequently, as shown in FIG. 8(c), a resist mask 180 having a certain pattern is formed on the laminated body 160 by, e.g., the photolithography process.

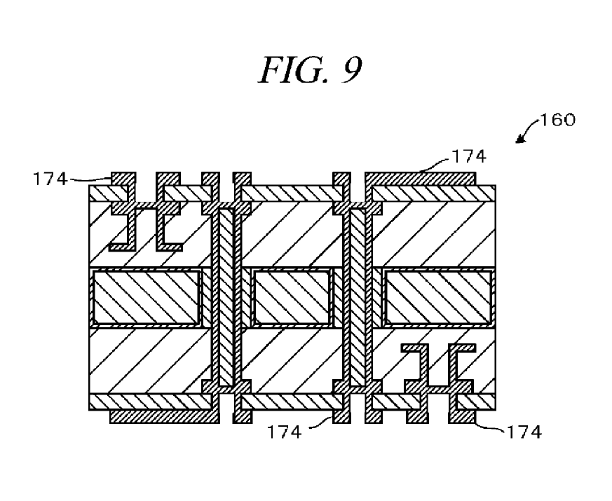

Then, as depicted in FIG. 9, the conductive layer 174 of the laminated body 160 is etched by using the resist mask 180 as a mask, and the conductive layer 174 is patterned to have a certain pattern. Thereafter, the resist mask 180 is removed.

In the circuit board for the semiconductor device inspection apparatus manufactured through the above-described process in accordance with the second illustrative embodiment, as in the first illustrative embodiment, the metal base body 110 formed by stacking and bonding the metal plates 101 made of, e.g., the 42 alloy having a low expansion coefficient is used as the core member, and the conductor pattern is formed on the inner wall surface of the through hole 102 and on the front surface and the rear surface of the metal base body 110 via the insulating layer. Accordingly, it is possible to obtain the circuit board for the semiconductor device inspection apparatus having a low expansion coefficient and high mechanical strength. Further, since the through hole 102 is formed in the metal plate 101 by the etching previously before the metal plates 101 are stacked and bonded, it is not required to drill a metal portion to form the through hole. Thus, the circuit board can be manufactured easily, so that the manufacturing cost thereof can be reduced.

While various aspects and embodiments have been described herein, other aspects and embodiments will be apparent to those skilled in the art. The various aspects and embodiments disclosed herein are not intended to be limiting and various modifications may be made without departing from the scope of the disclosure.

What is claimed is:

1. A circuit board for a semiconductor device inspection apparatus, comprising:
a metal base body obtained by stacking and bonding a multiple number of metal plates, each having a through hole formed by an etching, such that the through holes of the metal plates are overlapped with each other to form a through hole;
a resin layer formed on surfaces of the metal base body and on an inner wall surface of the through hole of the metal base body; and
a first conductor pattern formed to be electrically insulated from the metal base body by the resin layer.

2. The circuit board for the semiconductor device inspection apparatus of claim 1,
wherein a resin layer and a second conductor pattern are further formed on a surface of the first conductor pattern.

3. The circuit board for the semiconductor device inspection apparatus of claim 1,
wherein first electrodes are formed on one surface of the circuit board at a pitch corresponding to a pitch of electrodes on a test head of a tester for measuring an electrical characteristic of a semiconductor device, and second electrodes are formed on an opposite surface to the one surface of the circuit board at a pitch corresponding to a pitch of probes to be brought into contact with electrodes on the semiconductor device.

4. The circuit board for the semiconductor device inspection apparatus of claim 1,
wherein a material of each of the metal plates includes a 42 alloy.

5. The circuit board for the semiconductor device inspection apparatus of claim 2,
wherein a material of each of the metal plates includes a 42 alloy.

6. The circuit board for the semiconductor device inspection apparatus of claim 3,
wherein a material of each of the metal plates includes a 42 alloy.

7. A method for manufacturing a circuit board for a semiconductor device inspection apparatus, the method comprising:
forming a through hole at a portion of each of metal plates by an etching;
obtaining a metal base body by stacking and bonding the metal plates through a diffusion bonding such that the through holes are overlapped with each other to form a through hole;
forming a resin layer on surfaces of the metal base body and on an inner wall surface of the through hole of the metal base body; and
forming a conductor pattern electrically insulated from the metal base body by the resin layer.
